(19) United States
(12) Patent Application Publication
(10) Pub. No.: US 2004/0108573 A1
(43) Pub. Date: Jun. 10, 2004

(54) Use in semiconductor devices of dielectric antifuses grown on silicide

(75) Inventor: S. Brad Herner, San Jose, CA (US)

Correspondence Address: Matrix Semiconductor, Inc., 3230 Scott Blvd, Santa Clara, CA, 95054, US

(73) Assignee: MATRIX SEMICONDUCTOR, INC., Santa Clara, CA

(21) Appl. No.: 10/727,765

(22) Filed: Dec. 3, 2003

Related U.S. Application Data
(63) Continuation-in-part of application No. 10/095,962, filed on Mar. 13, 2002.

(51) Int. Cl. H01L 29/00

(52) U.S. Cl. 257/530

(57) ABSTRACT

A thin dielectric layer grown on a silicide layer can be used in many semiconductor devices. Such a grown dielectric, which may be, for example, a silicon oxide, silicon nitride, or silicon oxynitride dielectric layer, can advantageously be used as a dielectric antifuse. Such an antifuse paired with a diode or diode portions can operate as a memory cell, which is unprogrammed before rupture and programmed after rupture. Memory cell types using a dielectric grown on a silicide include Schottky diode portions separated by an antifuse, a Schottky diode separated from an adjacent conductor by an antifuse, and a junction diode separated from an adjacent conductor by an antifuse.

### RELATED APPLICATIONS

This application is a continuation-in-part of Hemer, U.S. patent application Ser. No. 10/095,962, “Silicide-Silicon Oxide-Semiconductor Antifuse Device and Method of Making,” filed Mar. 13, 2002, hereinafter the '962 application, hereby incorporated by reference.

This application is related to Petti et al., US Patent Application No., ______, “Semiconductor Device Including Junction Diode Contacting Contact-Antifuse Unit Comprising Silicide,” (attorney docket number MA-109) filed on even date herewith, hereby incorporated by reference.

### BACKGROUND OF THE INVENTION

The invention relates to the use in semiconductor devices of various dielectrics which are grown on a group of silicides. Such a dielectric can advantageously serve as an antifuse.

Thin dielectric layers have many uses in semiconductor devices. One role for a thin dielectric layer is as an antifuse. An antifuse, when first created, electrically separates two conductive elements. Once a sufficiently high voltage is applied across the antifuse, dielectric breakdown occurs, and the antifuse is permanently altered, rendering it conductive.

An antifuse can be formed by depositing a layer of dielectric material, but for many uses, grown dielectrics are superior. In general, grown dielectrics, for example oxides or nitrides formed by oxidizing or nitriding a suitable surface, are denser and higher quality than corresponding deposited oxides and nitrides. The most common grown dielectric used in semiconductor devices is silicon dioxide, which can easily be grown by oxidizing silicon.

In any device in which a dielectric is to be formed on top of silicon, silicon oxide is a practical solution. But some devices call for a dielectric layer on top of some other material, for example metals or suicides. In this case the antifuse has traditionally been deposited rather than grown and thus is generally lower quality. Many desirable semiconductor devices having thin grown dielectric layers, such as antifuses, would become possible if high-quality dielectrics could be grown on materials other than silicon.

There is a need, therefore, to grow dielectric layers of high quality on materials other than silicon.

### SUMMARY OF THE INVENTION

The present invention is defined by the following claims, and nothing in this section should be taken as a limitation on those claims. In general, the invention is directed to use in semiconductor devices of a dielectric grown on a silicide layer.

A first aspect of the invention provides for a semiconductor device comprising a silicide layer; and a grown dielectric layer on and in contact with the silicide layer, wherein the silicide layer and the grown dielectric layer are portions of the semiconductor device.

Another aspect of the invention provides for a monolithic three dimensional memory array comprising a first rail, wherein the first rail comprises a first silicon layer, a first silicide layer, and a first dielectric layer, the first silicide layer on and in contact with the first silicon layer and the first dielectric layer on and in contact with the first silicide layer; and a second rail, wherein the second rail comprises a second silicon layer, wherein the second silicon layer is on and in contact with the first dielectric layer.

Another aspect of the invention provides for a monolithic three dimensional memory array comprising a first memory level formed at a first height above a substrate, wherein the first memory level comprises a silicide layer and a dielectric layer grown on the silicide layer; and a second memory level formed at a second height above a substrate, the second height different from the first height.

Each of the aspects and embodiments of the invention can be used alone or in combination with one another.

The preferred aspects and embodiments will now be described with reference to the attached drawings.

### BRIEF DESCRIPTION OF THE DRAWINGS

FIG. 1 is a cross-section of an exemplary Schottky diode JAF device.

FIG. 2 is a cross-section of an exemplary Schottky diode non-JAF device.

FIGS. 3a-3c are cross-sectional views illustrating fabrication of an array of Schottky diode JAF devices according to the present invention.

FIGS. 4a-4c are cross-sectional views illustrating fabrication of an array of Schottky diode non-JAF devices according to the present invention.

FIG. 5 is a cross-sectional view illustrating an alternative Schottky diode non-JAF device according to the present invention.

FIG. 6 is a cross-sectional view illustrating a junction diode non-JAF device according to the present invention.

FIG. 7 is a cross-sectional view illustrating another junction diode non-JAF device according to the present invention.

### DETAILED DESCRIPTION OF THE INVENTION

The '962 application, from which the present application claims priority, teaches growing silicon oxide by exposing any of a group of suicides to an oxygen-containing ambient. The present application teaches growth of other dielectrics on a silicide and the use of these grown dielectrics in semiconductor devices.

A “grown” dielectric is one which is formed by exposing the silicide to, for example, an oxygen- and/or nitrogen-containing ambient in conditions that will cause atoms in the ambient to react with silicon from the silicide to form the dielectric. (Dielectrics grown in oxygen- and nitrogen-containing ambients are preferred, but dielectrics grown in other ambients not containing oxygen or nitrogen, so long as they are capable of providing atoms that will react with silicon from the silicide to form a dielectric, would also be considered grown dielectrics.) Exposing the silicide to an oxygen-containing ambient, for example, can form silicon oxide, while exposure to a nitrogen-containing ambient can form silicon nitride.

In preferred embodiments, the silicide was itself formed by depositing a suitable metal on silicon and annealing to form the silicide. Without wishing to be bound by any particular theory, it is believed that silicon from the underlying silicon layer in the stack diffuses through the silicide layer to react with the oxygen- and/or nitrogen-containing ambient to form a layer which substantially comprises silicon oxide, silicon nitride, or (if both oxygen and nitrogen are provided) silicon oxynitride. Alternatively, if a relatively thin dielectric is to be grown on a silicide which is not formed on an underlying silicon layer, it is believed that silicon can be depleted from the silicide, leaving a relatively silicon-poor silicide.

For example, a grown oxide may be formed by dry oxidation (i.e., exposing the silicide to an oxygen-containing gas), wet oxidation (e.g., exposing the silicide to hot steam), plasma enhanced oxidation (i.e., exposing the silicide to an oxygen plasma), chemical oxidation (i.e., exposing the silicide to an oxidizing liquid) and electrochemical oxidation (such as anodic oxidation). Similarly, a grown nitride may be formed using analogous methods using nitrogen, and a grown oxynitride formed by using both oxygen and nitrogen.

In contrast to a grown layer, a “deposited” layer is formed on a surface by providing atoms to the surface which do not necessarily react with the surface. For example, a silicon oxide layer can be deposited by chemical vapor deposition or sputtering.

Preferably, the silicon oxide, silicon nitride, or silicon oxynitride layer is thermally grown at a temperature above room temperature by dry, wet or plasma oxidation and/or nitridation. Most preferably, the silicon oxide, silicon nitride, or silicon oxynitride layer is grown by exposing the silicide layer to an oxygen atmosphere, a nitrogen atmosphere, or both, in a rapid thermal annealing system. In general, silicon oxide is formed by oxidizing a silicide and silicon nitride is formed by nitriding a silicide.

The present application most preferably teaches growing silicon oxide on a silicide by exposing the silicide to an oxygen-containing ambient, growing silicon nitride on a silicide by exposing the silicide to a nitrogen-containing ambient, or growing silicon oxynitride on a silicide by exposing the silicide to an oxygen- and nitrogen-containing ambient. Any of these methods can be combined; for example a silicon oxide can be grown, then exposed to a nitrogen-containing ambient to form an oxynitride. Similarly, a silicon nitride can be grown, then exposed to an oxygen-containing ambient to form an oxynitride.

Other less preferred dielectrics can also be formed by analogous methods; for example silicon carbide can be formed by exposing silicide to a carbon ambient. This reaction requires much higher temperatures, however, making its use impractical in most devices.

The preferred suicides upon which to grow a silicon-containing dielectric according to the present invention are cobalt silicide, platinum silicide, nickel silicide (i.e., NiSi and NiSi₂), chromium silicide, palladium silicide, tantalum silicide, and niobium silicide. Cobalt silicide is most preferred.

In addition to being denser and higher quality than corresponding deposited dielectrics, in general high-quality grown dielectrics can be made thinner than deposited dielectrics. A dielectric grown on a silicide according to the present invention can have a thickness of about 200 angstroms or less, and in some embodiments 50 angstroms or less.

A silicon-containing dielectric grown on a silicide can be used to advantage in a wide variety of devices. Just a few will be described herein. Any semiconductor device comprising a silicide layer and a grown dielectric layer on and in contact with the silicide layer, however, falls within the scope of the present invention.

It is known to pair antifuses and diodes or diode portions to operate as memory cells. An antifuse-diode memory cell is in an unprogrammed state before the antifuse layer is ruptured (when no circuit is present) and is in a programmed state after antifuse rupture (when a circuit is formed.) An antifuse in an antifuse-diode device can be grown on a silicide according to the present invention, making possible several families of devices.

Two commonly used classes of diodes are Schottky diodes and junction diodes. A Schottky diode includes a metal or metal-like material (a silicide, for example) adjacent to a semiconductor material and conducts current more easily in one direction than the other. The term junction diode is used herein to refer to a semiconductor device with the property of conducting current more easily in one direction than the other, having two terminal electrodes, and made of semiconducting material which is p-type at one electrode and n-type at the other.

The antifuse and diode portions in an antifuse-diode memory cell can be arranged different ways. An antifuse can separate diode portions; for example it can be interposed between the metal and the semiconductor of a Schottky diode, or between p-type and n-type semiconductor material in a junction diode. A device in which the antifuse is formed between diode portions that operate as a diode only after antifuse rupture will be called a junction-antifuse (JAF) device. FIG. 1 shows a JAF device, in which antifuse layer 6 separates semiconductor layer 4 from metal layer 8 in a memory cell 2. Semiconductor layer 4 and metal layer 8 are Schottky diode portions, and memory cell 2 is a Schottky diode JAF device.

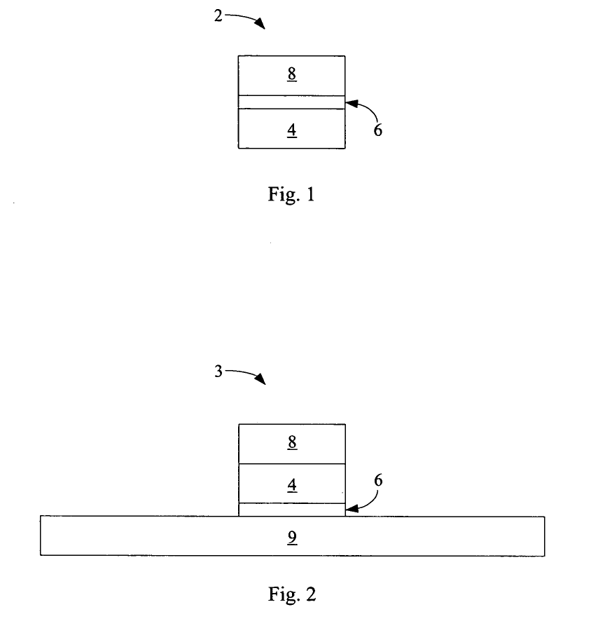

Alternatively, an intact Schottky or junction diode, with no antifuse interposed between diode portions, can be formed with an antifuse separating the diode from an adjacent conductor. Such a device will be called a non-JAF device. FIG. 2 shows a non-JAF device, in which antifuse layer 6 separates an intact Schottky diode, which is formed by semiconductor layer 4 and metal layer 8, from underlying conductor 9. Memory cell 3 is a Schottky diode non-JAF device.

Specific examples of several devices in each of the named device families will be provided. It will be understood that these are examples only, and many other configurations are possible. Details concerning materials, conductivity types, conditions, and steps will be described, but it will be apparent to those skilled in the art that many of these details can be changed, omitted, or supplemented while the result still falls within the scope of the invention.

Schottky Diode JAF Devices

In one group of preferred embodiments, an antifuse comprising a silicon-containing dielectric, for example silicon oxide, silicon nitride, or silicon oxynitride, is grown on a silicide according to the present invention. Depositing a semiconductor, preferably silicon, on the antifuse creates a Schottky diode JAF device, in which an antifuse separates the diode portions, which are a silicide and a semiconductor. Many silicides are highly conductive and can take the place of a metal in a Schottky diode.

The preferred silicides upon which to grow a silicon-containing dielectric according to the present invention are cobalt silicide, platinum silicide, nickel silicide (i.e., NiSi and NiSi₂), chromium silicide, palladium silicide, tantalum silicide, and niobium silicide. Cobalt silicide is most preferred.

A monolithic three dimensional memory array will be described, the array comprising memory cells which are Schottky diode JAF devices comprising antifuses made according to the present invention. Specific materials, conductivity types, conditions, and steps will be described, but it will be apparent to those skilled in the art that many of these details can be changed, omitted, or supplemented while the result still falls within the scope of the invention. A related memory array is disclosed in the '962 application, and a more detailed description is provided in that application. The description provided herein is simplified for clarity, but none of the relevant teachings of the '962 application is intended to be excluded.

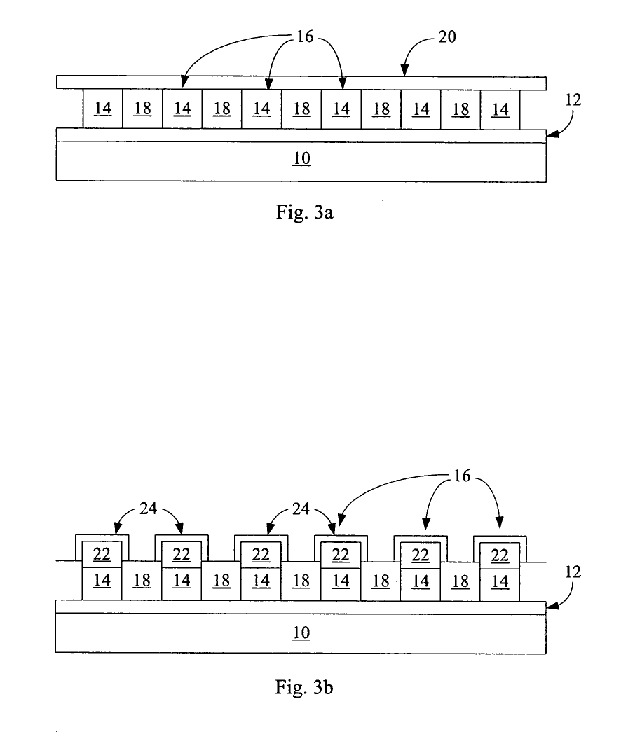

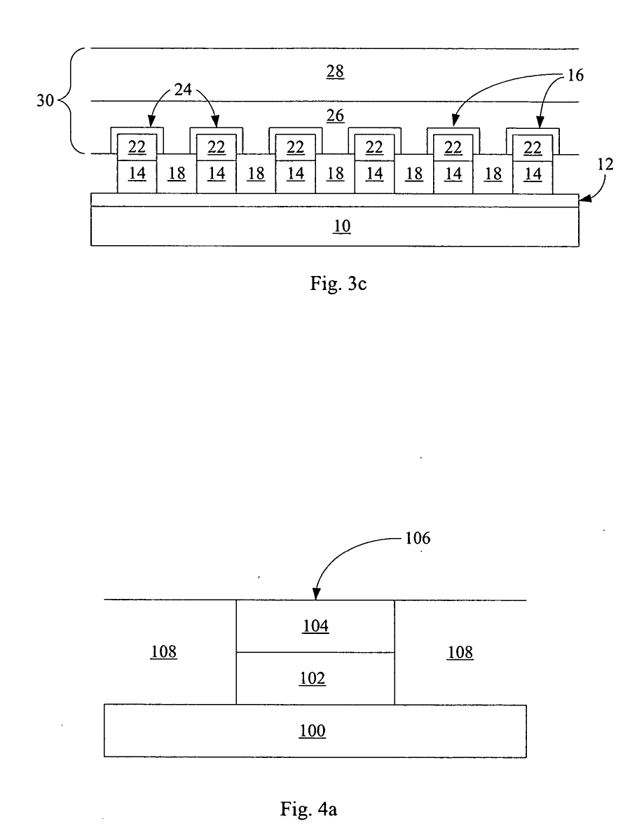

Turning to FIG. 3a, formation of the array begins over a suitable substrate, for example a monocrystalline silicon wafer 10, which may be insulated from layers to be formed by dielectric layer 12. Clearly these layers are illustrative only, and more, fewer, or different layers may be present.

A first polycrystalline silicon (herein called polysilicon) layer 14 is deposited, then patterned and etched to form first rails 16, shown in FIG. 3a in cross-section. Dielectric fill 18, for example silicon dioxide, is deposited on and between first rails 16. The fill 18 is planarized, for example by chemical mechanical polishing (CMP), to expose the tops of first rails 16.

Metal layer 20 is deposited on first rails 16 and gap fill 18. Metal layer 20 is preferably cobalt. Cobalt can be deposited by any conventional method, for example by sputtering. Other metals can be used in place of cobalt, including platinum, nickel, chromium, palladium, tantalum, and niobium. For simplicity, this description will detail the use of cobalt, but it will be understood that any of these other metals can be substituted as appropriate.

Optionally, a capping layer of about 200 angstroms, preferably of titanium or titanium nitride, is deposited on the cobalt (not shown.) The titanium or titanium nitride cap assists in the subsequent conversion of the cobalt layer to cobalt silicide.

Turning to FIG. 3b, an anneal is performed at a suitable temperature to react the cobalt with the polysilicon 14 of the exposed first rails 16 to form cobalt silicide 22 on the rails 16 only; no silicide is formed where the cobalt overlies dielectric fill 18. For example, the anneal may be performed in a rapid thermal annealing system at about 400 to about 700 degrees C. for about 20 to about 100 seconds, preferably at about 500 degrees C. for about 30 seconds. Some of the silicon of polysilicon layer 14 is consumed in the reaction. The capping layer and unreacted portions of the cobalt are removed by a selective etch. Any etching medium which selectively etches the capping layer and the unreacted cobalt while leaving cobalt silicide may be used. Preferably, selective wet etching is used.

A second anneal is performed to homogenize the cobalt silicide 22 to CoSi₂. This anneal is performed at a temperature from about 550 degrees C. to about 800 degrees C. for about 30 to about 60 seconds, preferably at about 740 degrees C. for about 30 seconds. This second anneal can be performed at any time after the first. In a multi-level memory array, preferably a single anneal is performed after all of the memory levels are constructed to homogenize the cobalt silicide. Alternatively, this anneal can be performed in the same thermal step used to form the grown antifuse.

Next a dielectric antifuse layer 24 is thermally grown on the cobalt silicide 22. For example, silicon oxide is grown by exposing the silicide layer 22 to an oxygen atmosphere in a rapid thermal annealing system, preferably at about 670 to about 750 degrees C. for about 20 to about 60 seconds. Alternatively, the second cobalt silicide anneal can be combined with antifuse growth. Other methods may be used, including any of those taught in the '962 application. The structure at this point is shown in FIG. 3b.

Other dielectrics can be grown instead. A silicon nitride layer can be grown, for example by flowing about 4.0 liters/minute of NH₃ at about 750 degrees for about 60 seconds at atmospheric pressure; the ramp rate is about 50 degrees/second. Alternate source gases that may be used are NO and N₂O. A silicon oxynitride layer can be grown by using combinations of source gases including O₂, NH₃, N₂O, NO, H₂, HCl, and H₂O. An oxynitride can also be formed by nitriding a previously formed oxide layer or by oxidizing a previously formed nitride layer. Any combination of these methods can be used.

If the antifuse is silicon oxide, the thickness of the resulting antifuse is preferably between about 25 and 200 angstroms, more preferably between about 50 and about 100 angstroms, most preferably about 60 angstroms. In general, these thicknesses are preferred when a grown silicon oxide antifuse according to the present invention separates the silicide from a semiconductor material.

If a silicon oxide antifuse layer is grown, the silicon oxide antifuse layer preferably comprises stoichiometric silicon dioxide, but also may include a non-stoichiometric silicon oxide layer (i.e., a layer having a silicon to oxygen ratio of other than 1:2.) Similarly, silicon nitride may or may not be stoichiometric Si₃N₄.

Turning to FIG. 3c, semiconductor layer 26 is deposited next. Any semiconductor material can be used, but silicon is preferred. Lightly doped n-type or intrinsic polysilicon is most preferred. Heavily doped semiconductor layer 28 is deposited next; it is preferably n-type polysilicon, most preferably heavily doped n-type polysilicon. Layers 26 and 28 can be doped by any known method, such as in-situ doping or ion implantation.

Next layers 26 and 28 are patterned and etched to form second rails 30, which are preferably substantially perpendicular to first rails 16. A dielectric fill (not shown) is deposited over and between second rails 30, then is planarized, for example by CMP, exposing heavily doped semiconductor layer 28 at the tops of second rails 30.

It will be seen that for any one of first rails 16 and second rails 30, cobalt silicide layer 22, antifuse layer 24, and lightly doped silicon layer 26 form an incipient Schottky diode, which will become a Schottky diode when the antifuse 24 is ruptured. That is, silicide layer 22 and silicon layer 26 operate as a Schottky diode after dielectric rupture of antifuse layer 24.

Many possible methods can be employed to form additional memory levels and thus form a monolithic three dimensional array. For example, a dielectric layer can be formed over second rails 30 and planarized, for example by CMP or etchback, then additional rails formed atop the dielectric using the methods described to form an additional memory level. These steps can be repeated to form additional memory levels.

Vyvoda, U.S. patent application Ser. No. 10/440,882, “Rail Schottky Device and Method of Making,” filed May 19, 2003, owned by the assignee of the present invention and hereby incorporated by reference, teaches a monolithic three dimensional memory array comprising Schottky diode components separated by antifuses. The Schottky diodes are vertically oriented and disposed on alternating levels. Those on odd levels are “rightside-up” with antifuse over the metal or metallic material, and those on even levels are “upside down” with a metal or metallic material over the antifuse. Both antifuses are preferably grown oxides. As another alternative, the rightside-up Schottky diodes of Vyvoda can be the Schottky JAF diodes just described in the instant application, with cobalt silicide (or one of the other eligible silicides) used as the metal, and a grown dielectric, for example silicon oxide, silicon nitride, or silicon oxynitride grown according to the present invention, as the antifuse. The upside-down Schottky diodes of Vyvoda can be constructed next, then the entire structure repeated as taught by Vyvoda.

In the arrays just described, memory cells comprise a silicide layer, a grown dielectric layer on and in contact with the silicide layer, and a conductive layer on and in contact with the grown dielectric layer, wherein the conductive layer comprises silicon. The silicon is a portion of a Schottky diode after breakdown of the grown dielectric layer. The Schottky diode is a portion of a memory cell, which is a portion of a memory array. The memory array may be a monolithic three dimensional memory array. Further, the silicide layer is formed on and in contact with a silicon layer.

Schottky Diode Non-JAF Devices

Memory arrays can also be formed in which the memory cells are intact Schottky diodes separated from adjacent conductors by a dielectric grown on a silicide, the dielectric serving as an antifuse. Many configurations are possible; only a few will be described here.

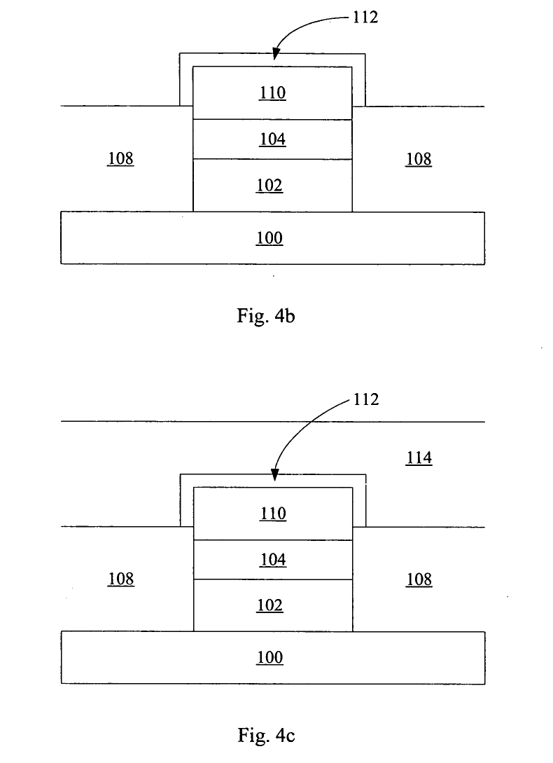

FIG. 4a shows a first conductive layer 100 which may be, for example, titanium silicide, cobalt silicide, titanium nitride, etc. Lightly doped n-type or intrinsic polysilicon layer 102 is deposited, followed by heavily doped n-type polysilicon layer 104. Layers 102 and 104 are patterned and etched to form first rails 106, shown in cross-section. Gaps between the rails 106 are filled with dielectric fill 108, then fill 108 is planarized, for example by CMP, to expose heavily doped polysilicon layer 104 at the top of rails 106. The result is shown in FIG. 4a.

Next a metal, preferably cobalt, is deposited and annealed to selectively form cobalt silicide, then the unreacted cobalt removed according to the methods described earlier. It will be understood that any of the other metals named earlier (platinum, nickel, chromium, palladium, tantalum, and niobium) could be used instead of cobalt. A dielectric antifuse, preferably silicon oxide, silicon nitride, or silicon oxynitride, is grown on cobalt silicide according to the methods described earlier. The resulting structure, with cobalt silicide layer 110 and antifuse layer 112, is shown in FIG. 4b. It will be seen that a portion of silicon layer 104 was consumed by the silicide process.

Finally, as shown in FIG. 4c, a conductive material 114 is formed on antifuse layer 112, for example a metal, a silicide, or titanium nitride. Titanium nitride is preferred. In some embodiments it may be preferred to use a titanium nitride layer deposited using a physical vapor deposition (PVD) process without applied self-bias; a PVD process is typically performed at about 0.5 to about 5 mTorr. This technique is used, rather than a self-biased PVD process, to avoid damaging the fragile grown antifuse layer 112. Titanium nitride formed using this method has lower density and higher resistivity than titanium nitride formed using more conventional methods, as is fully described in Hemer, U.S. patent application Ser. No. 10/611,245, “Low-Density, High-Resistivity Titanium Nitride Layer for Use as a Contact for Low-Leakage Dielectric Layers,” filed Jun. 30, 2003, hereinafter the '245 application, hereby incorporated by reference. This low-density, high-resistivity titanium nitride typically has a density less than about 4.0 grams per cubic cm and resistivity greater than about 300 microOhm-cms. Preferably a portion of the titanium nitride layer having a thickness of at least about 20 angstroms is the low-density, high-resistivity titanium nitride described in the '245 application. An additional advantage gained by using low-density, high-resistivity titanium nitride according to the '245 application is that leakage current across the grown antifuse before rupture will be reduced. This low-leakage characteristic is particularly advantageous when paired with a silicon nitride antifuse. Other metals that can be use in an analogous low-density, high-resistivity form are tungsten nitride, tantalum nitride, titanium tungsten, tungsten, and aluminum. Another conductive material (not shown), for example tungsten or conventional, dense titanium nitride is preferably formed on titanium nitride layer 114.

Conductive layer 100 and lightly doped or intrinsic polysilicon layer 102 form a Schottky diode. Heavily doped polysilicon layer 104 provides good ohmic contact to cobalt silicide layer 110. Breakdown of grown dielectric layer 112 creates an electrical connection between the Schottky diode and conductor 114.

In preferred embodiments, each memory cell comprises a silicide layer, a grown dielectric layer on and in contact with the silicide layer, and a conductive layer on and in contact with the grown dielectric layer, wherein the conductive layer comprises a metal, a silicide, or titanium nitride. Multiple memory levels, each comprising such memory cells, can be stacked to form a monolithic three dimensional memory array.

In this description, polysilicon layers 102 and 104 were patterned as rails. Other shapes are possible; for example, they could be patterned as isolated pillars.

In the preceding example, the antifuse is formed between a Schottky diode and an overlying conductor. In the next example, an antifuse will be formed between a Schottky diode and an underlying conductor.

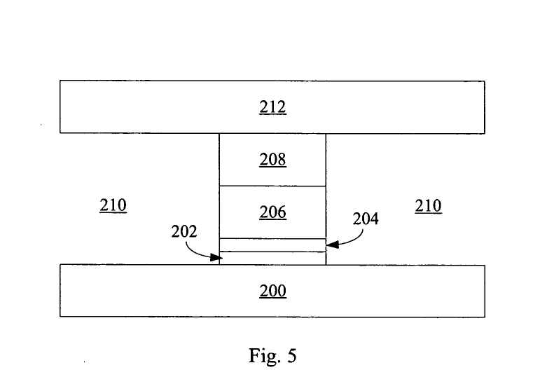

FIG. 5 shows an alternative memory cell. Dielectric antifuse layer 202 (preferably silicon oxide, silicon nitride, or silicon oxynitride) is grown on cobalt silicide layer 200 (or any of the other named silicides.) Cobalt silicide layer 200 may have been formed by siliciding an underlying silicon layer (not shown.) Most preferably, a silicon layer was deposited, patterned into rails, the gaps between the rails filled with dielectric fill, then the dielectric fill planarized to expose the tops of the rails; the selective formation of cobalt silicide on the silicon rails then proceeds as in prior embodiments.

A thin layer of a metal, silicide, or metallic material is formed on dielectric antifuse layer 202, preferably titanium nitride 204, in some embodiments most preferably low-density, high-resistivity titanium nitride formed according to the '245 application. Preferably a portion of titanium nitride layer 204 having a thickness of at least about 20 angstroms is the low-density, high-resistivity titanium nitride described in the '245 application. Lightly doped n-type or intrinsic polysilicon layer 206 and heavily doped n-type polysilicon layer 208 are preferably formed as shown. Layers 202, 204, 206, and 208 are patterned and etched, for example into rails, as shown, and dielectric fill 210 is deposited on and between the rails.

The fill is planarized, for example by CMP, to expose polysilicon layer 208 at the tops of the rails. Optionally a layer of silicide, preferably titanium silicide or cobalt silicide (not shown) can be formed on polysilicon layer 208. Such a layer is preferably formed by, for example, depositing titanium, annealing to form titanium silicide, then selectively removing unreacted titanium using a wet etch. Next conductive layer 212 is deposited, along with additional conductive layers if desired, and patterned, for example into rails. Conductive layer 212 can be titanium nitride, titanium silicide, cobalt silicide, a metal, or any other suitable conductive material, which is deposited, then patterned and etched to form conductors. These conductors are preferably formed as substantially parallel rails, preferably substantially perpendicular to the underlying rails.

In this cell an intact Schottky diode exists between lightly doped n-type or intrinsic silicon layer 206 and titanium nitride layer 204. Breakdown of grown dielectric layer 202 creates an electrical connection between the Schottky diode and conductor 200. Each memory cell comprises a silicide layer, a grown dielectric layer on and in contact with the silicide layer, and a conductive layer on and in contact with the grown dielectric layer, wherein the conductive layer comprises a metal or titanium nitride.

Any of the Schottky diode memory cells described here can be arranged in various configurations, and can be stacked to form multiple memory levels. Any of these memory cells can be a portion of a memory array, wherein the memory array is a monolithic three dimensional memory array. Such a memory array is a multilevel array, comprising a first memory level formed at a first height above a substrate, wherein the first memory level comprises a silicide layer and a dielectric layer grown on the silicide layer; and a second memory level formed at a second height above a substrate, the second height different from the first height.

Junction Diode Non-JAF Devices

Petti et al., filed on even date herewith, teaches a junction diode separated from an adjacent conductor by an antifuse, wherein the antifuse is a dielectric grown on silicide according to the present invention.

Two preferred embodiments from Petti et al. will be considered. In the first, the antifuse grown on a silicide separates the junction diode from an overlying conductor, and in the second, the antifuse grown on a silicide separates the junction diode from an underlying conductor.

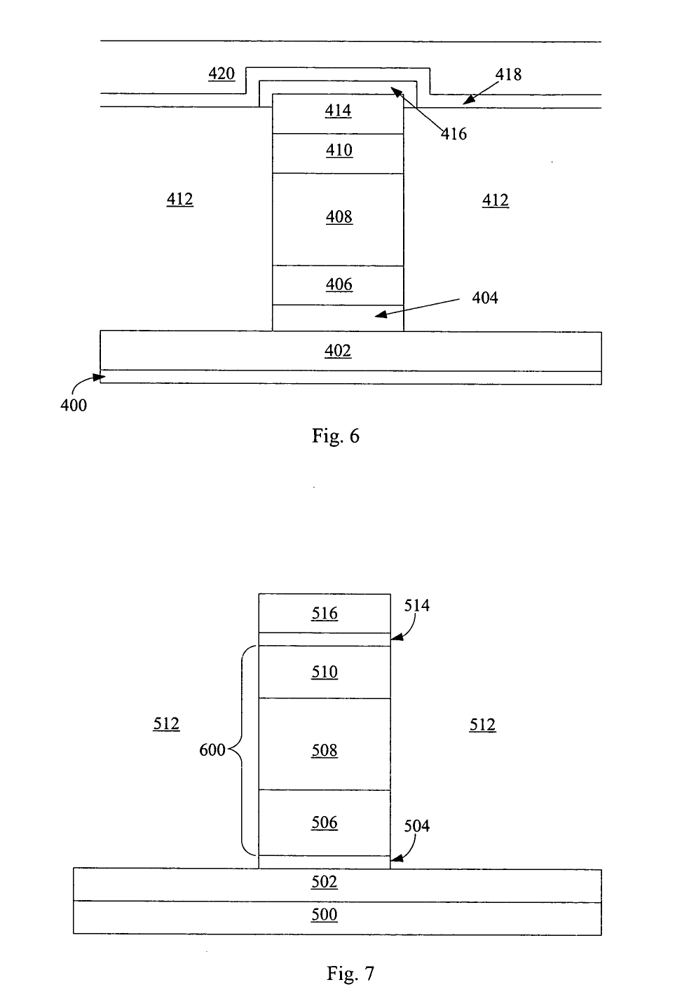

In the first preferred embodiment from Petti et al., shown in FIG. 6, conductors are formed of one or more conductive layers, for example titanium nitride layer 400 and tungsten layer 402, which are deposited, then patterned and etched into substantially parallel rails. These rails extend across the page. Gaps between them are filled with dielectric (not shown) and the dielectric fill is planarized to expose layer 402 at the top of the conductor.

An optional titanium nitride barrier layer 404 is deposited next, followed by a heavily doped layer 406 of polysilicon of a first conductivity type, for example p-type. Next layers 408 and 410 are deposited. Layer 408 is polysilicon of a second conductivity type, for example n-type. Intrinsic polysilicon tends to behave as if slightly n-doped, so this layer may be intrinsic. Layer 410 is heavily doped, for example with n-type dopants. It can be in-situ doped during deposition, or can be deposited intrinsic and doped later, for example by ion implantation.

Layers 410, 408, 406, and 404 are patterned and etched into pillars, and the gaps between them filled with dielectric fill 412. The fill is planarized, for example by CMP, to expose heavily doped polysilicon layer 410 at the tops of the pillars. If heavily doped polysilicon layer 410 is to be doped by ion implantation, the implantation is preferably performed at this point.

Next a cobalt silicide layer 414 (or one of the other silicides named throughout) is selectively grown on silicon layer 410 by the methods described earlier (deposit cobalt, perform a first anneal to form a silicide, remove unreacted cobalt, and perform a second anneal to convert the silicide to a low-resistivity form.) A dielectric layer 416, preferably silicon oxide, silicon nitride, or silicon oxynitride, is grown on silicide layer 414 as previously described. Layers to form the next conductors are then deposited, preferably titanium nitride layer 418 and tungsten layer 420, as shown. In some embodiments, titanium nitride layer 418 is preferably low-density, high-resistivity tungsten formed according to the methods of the '245 application to avoid damage to antifuse layer 416. Preferably a portion of the titanium nitride layer 418 having a thickness of at least about 20 angstroms is the low-density, high-resistivity titanium nitride described in the '245 application. Use of low-density, high-resistivity titanium nitride may provide additional advantage in that it will decrease leakage current across the antifuse before the cell is programmed. Titanium nitride layer 418 and tungsten layer 420 will then be patterned and etched to form conductors which are in contact with the underlying etched pillars and are preferably substantially perpendicular to the conductors underlying the pillars.

In the second preferred embodiment of Petti et al., shown in FIG. 7, first conductors are formed of silicon layer 500, which are patterned and etched into substantially parallel rails, shown extending across the page. Gaps between them are filled with dielectric (not shown) and the dielectric fill is planarized to expose silicon layer 500 at the top of the conductor. A layer 502 of cobalt silicide (or one of the other eligible silicides) is selectively formed on silicon layer 500 according to the methods described in previous embodiments. Silicide layer 502 serves as a conductor, so it should be thicker than most of the silicide layers described in previous embodiments. About 300 or 400 angstroms of deposited cobalt, for example, will result in about 900 to about 1200 angstroms of cobalt silicide. Dielectric layer 504 (silicon oxide, silicon nitride, or silicon oxynitride) is selectively grown on silicide layer 502 as described earlier.

A thin layer of titanium nitride (not shown) is optionally deposited on antifuse layer 504; it may be low-density, high-resistivity titanium nitride according to the '245 application. This layer can also be omitted. Next a junction diode 600 is formed, comprising heavily doped semiconductor layer 506 of a first conductivity type, lightly doped (or intrinsic) semiconductor layer 508 of a second conductivity type, or and heavily doped semiconductor layer 510 of the second conductivity type. These layers can be doped by any known method including in-situ doping or ion implantation. Silicon is preferred, but another semiconductor material, for example silicon-germanium or germanium, could replace the silicon forming this junction diode.

Layers 510, 508, and 506, the titanium nitride layer below layer 506, if present, and 504 are patterned and etched to form pillars. The gaps between are filled with dielectric fill 512, and the fill is planarized, for example by CMP, to expose heavily doped polysilicon layer 510 at the tops of the pillars. If heavily doped polysilicon layer 510 is to be doped by ion implantation, implantation is preferably performed at this point.

Next overlying conductors are formed. Conductive layers 514, preferably titanium nitride, and 516, preferably tungsten, are deposited, then patterned and etched to form substantially parallel conductors. These conductors are preferably substantially perpendicular to the underlying conductors formed of silicon layer 500 and cobalt silicide layer 502, and thus extend into the page and are shown in FIG. 7 in cross-section. Titanium layer 514 is not deposited on an antifuse layer, and thus is preferably traditional dense titanium nitride.

Petti et al. describes how to construct a monolithic three dimensional memory array comprising either or both of these junction diode memory cells separated from a conductor by a dielectric antifuse grown on a silicide. Such a memory array is a multilevel array, comprising a first memory level formed at a first height above a substrate, wherein the first memory level comprises a silicide layer and a dielectric layer grown on the silicide layer; and a second memory level formed at a second height above a substrate, the second height different from the first height.

A more detailed description of how to construct a memory array using junction diodes and antifuses grown on a silicide appears in Petti et al. The description here is simplified for clarity, but none of the teachings of Petti et al. is intended to be excluded. The memory array of Petti et al. is a variation of a memory array described in detail in Herner et al., U.S. patent application Ser. No. 10/326,470, “An Improved Method for Making High Density Nonvolatile Memory,” filed Dec. 19, 2002, hereby incorporated by reference. None of the relevant teachings of Herner et al. is intended to be excluded.

The foregoing detailed description has described only a few of the many forms that this invention can take. For this reason, this detailed description is intended by way of illustration, and not by way of limitation. It is only the following claims, including all equivalents, which are intended to define the scope of this invention.

What is claimed is:

1. A semiconductor device comprising:
a silicide layer; and
a grown dielectric layer on and in contact with the silicide layer, wherein the silicide layer and the grown dielectric layer are portions of the semiconductor device.

2. The semiconductor device of claim 1 wherein the silicide is selected from the group consisting of cobalt silicide, platinum silicide, nickel silicide, chromium silicide, palladium silicide, tantalum silicide, and niobium silicide.

3. The semiconductor device of claim 2 wherein the grown dielectric layer comprises silicon oxide.

4. The semiconductor device of claim 2 wherein the grown dielectric layer comprises nitrogen.

5. The semiconductor device of claim 4 wherein the grown dielectric layer comprises silicon nitride or silicon oxynitride.

6. The semiconductor device of claim 2 further comprising a conductive layer on and in contact with the grown dielectric layer.

7. The semiconductor device of claim 6 wherein the grown dielectric layer is less than about 50 angstroms thick.

8. The semiconductor device of claim 6 further comprising a first silicon layer, the silicide layer on and in contact with the first silicon layer.

9. The semiconductor device of claim 6 wherein the conductive layer comprises silicon.

10. The semiconductor device of claim 9 wherein the conductive layer forms a portion of a Schottky diode.

11. The semiconductor device of claim 10 wherein the conductive layer forms a portion of a Schottky diode after breakdown of the grown dielectric layer.

12. The semiconductor device of claim 11 wherein the Schottky diode is a portion of a memory cell.

13. The semiconductor device of claim 12 wherein the memory cell is a portion of a memory array.

14. The semiconductor device of claim 13 wherein the memory array is a monolithic three dimensional memory array.

15. The semiconductor device of claim 6 wherein the conductive layer comprises a metal.

16. The semiconductor device of claim 15 wherein the conductive layer forms a portion of a Schottky diode.

17. The semiconductor device of claim 16 wherein breakdown of the grown dielectric layer creates an electrical connection between the Schottky diode and a conductor.

18. The semiconductor device of claim 17 wherein the Schottky diode is a portion of a memory cell.

19. The semiconductor device of claim 18 wherein the memory cell is a portion of a memory array.

20. The semiconductor device of claim 19 wherein the memory array is a monolithic three dimensional memory array.

21. The semiconductor device of claim 6 wherein the conductive layer comprises a silicide.

22. The semiconductor device of claim 21 wherein the conductive layer forms a portion of a Schottky diode.

23. The semiconductor device of claim 22 wherein breakdown of the grown dielectric layer creates an electrical connection between the Schottky diode and a conductor.

24. The semiconductor device of claim 23 wherein the Schottky diode is a portion of a memory cell.

25. The semiconductor device of claim 24 wherein the memory cell is a portion of a memory array.

26. The semiconductor device of claim 25 wherein the memory array is a monolithic three dimensional memory array.

27. The semiconductor device of claim 6 wherein the conductive layer comprises titanium nitride.

28. The semiconductor device of claim 27 wherein the conductive layer forms a portion of a Schottky diode.

29. The semiconductor device of claim 28 wherein breakdown of the grown dielectric layer creates an electrical connection between the Schottky diode and a conductor.

30. The semiconductor device of claim 29 wherein the Schottky diode is a portion of a memory cell.

31. The semiconductor device of claim 30 wherein the memory cell is a portion of a memory array.

32. The semiconductor device of claim 31 wherein the memory array is a monolithic three dimensional memory array.

33. The semiconductor device of claim 27 wherein, for any portion of the conductive layer more than about 20 angstroms thick, the density of the titanium nitride is less than about 4.0 grams per cubic cm.

34. The semiconductor device of claim 27 wherein, for any portion of the film more than about 20 angstroms thick, the resistivity of the titanium nitride is greater than about 300 microOhm-cms.

35. The semiconductor device of claim 2 wherein the grown dielectric layer was grown by oxidizing or nitriding the silicide.

36. The semiconductor device of claim 2 wherein breakdown of the grown dielectric layer creates an electrical connection between a Schottky diode and a conductor.

37. The semiconductor device of claim 36 wherein the Schottky diode is a portion of a memory cell.

38. The semiconductor device of claim 37 wherein the memory cell is a portion of a memory array.

39. The semiconductor device of claim 38 wherein the memory array is a monolithic three dimensional memory array.

40. The semiconductor device of claim 36 wherein the silicide is a portion of the Schottky diode.

41. The semiconductor device of claim 2 wherein breakdown of the grown dielectric layer creates an electrical connection between portions of a Schottky diode.

42. The semiconductor device of claim 41 wherein the Schottky diode is a portion of a memory cell.

43. The semiconductor device of claim 42 wherein the memory cell is a portion of a memory array.

44. The semiconductor device of claim 43 wherein the memory array is a monolithic three dimensional memory array.

45. A monolithic three dimensional memory array comprising:
a first rail, wherein the first rail comprises a first silicon layer, a first silicide layer, and a first dielectric layer, the first silicide layer on and in contact with the first silicon layer and the first dielectric layer on and in contact with the first silicide layer; and
a second rail, wherein the second rail comprises a second silicon layer,
wherein the second silicon layer is on and in contact with the first dielectric layer.

46. The array of claim 45 wherein the first silicide layer comprises a silicide selected from the group consisting of cobalt silicide, platinum silicide, nickel silicide, chromium silicide, palladium silicide, tantalum silicide, and niobium silicide.

47. The array of claim 46 wherein the first dielectric layer is grown.

48. The array of claim 47 wherein the first silicide layer and the second silicon layer operate as a Schottky diode after dielectric rupture of the first dielectric layer.

49. A monolithic three dimensional memory array comprising:
a first memory level formed at a first height above a substrate, wherein the first memory level comprises a silicide layer and a dielectric layer grown on the silicide layer; and
a second memory level formed at a second height above a substrate, the second height different from the first height.

50. The array of claim 49 wherein the silicide is selected from the group consisting of cobalt silicide, platinum silicide, nickel silicide, chromium silicide, palladium silicide, tantalum silicide, and niobium silicide.

51. The array of claim 50 wherein the dielectric layer comprises silicon oxide.

52. The array of claim 50 wherein the dielectric layer comprises nitrogen.

53. The array of claim 52 wherein the dielectric layer comprises silicon nitride.

54. The array of claim 52 wherein the dielectric layer comprises silicon oxynitride.

55. The array of claim 50 further comprising junction diodes.

56. The array of claim 50 further comprising a) Schottky diodes or b) Schottky diode portions, wherein the diode portions operate as a Schottky diode after dielectric rupture of an antifuse.
